(19) United States
(12) Patent Application Publication
(10) Pub. No.: US 2026/0163248 A1
(43) Pub. Date: Jun. 11, 2026

(54) LOW-FREQUENCY MULTIFERROIC MECHANICAL ANTENNA AMPLIFIED WITH MULTIFUNCTIONAL METAMATERIAL BEAM

(71) Applicant: Shanghai Jiao Tong University, Shanghai (CN)

(72) Inventors: Yao Wang, Shanghai (CN); Congyi Guan, Shanghai (CN); Ning Xiao, Shanghai (CN); Qiuyue He, Shanghai (CN)

(21) Appl. No.: 19/052,678

(22) Filed: Feb. 13, 2025

(30) Foreign Application Priority Data
Dec. 9, 2024 (CN) 202411803773.3

(51) Int. Cl. H01Q 15/00; H02J 50/00; H03H 9/02; H03H 9/72

(52) U.S. Cl. CPC H01Q 15/0086; H03H 9/02574; H03H 9/725; H02J 50/001

(57) ABSTRACT

A low-frequency multiferroic mechanical antenna amplified with a multifunctional metamaterial beam is provided, relating to the technical field of antennas. The array includes multiple unit arrays each consisting of a strong-hysteresis piezomagnetic layer, a high-magnetic-permeability piezomagnetic film unit, and a piezoelectric layer, a grid-shaped shuttle composite beam with variable stiffness that is composed of a first elastic substrate, a flexible piezoelectric material PVDF layer, and a second elastic substrate, a permanent magnet, an energy harvesting circuit, and a negative resistance circuit. Elastic standing waves generated by a piezoelectric array under excitation enhances a magnetic moment oscillation effect of the permanent magnet at the end of the beam through variable stiffness characteristics of the elastic substrate in the composite beam and strain convergence characteristics of a shuttle-shaped structure; vibration of the permanent magnet and a magnetostrictive effect of a piezomagnetic film together generate an emitted alternating magnetic field.

### CROSS REFERENCE TO RELATED APPLICATION

This patent application claims the benefit and priority of Chinese Patent Application No. 2024118037733 filed with the China National Intellectual Property Administration on Dec. 9, 2024, the disclosure of which is incorporated by reference herein in its entirety as part of the present application.

### TECHNICAL FIELD

The present disclosure relates to the technical field of antennas, and in particular, to a low-frequency multiferroic mechanical antenna amplified with a multifunctional metamaterial beam.

### BACKGROUND

Radio frequency communication technologies (such as Bluetooth and 5G) are widely used in daily life; however, they experience severe path loss in high conductivity environments such as underground or underwater. In contrast, very low frequency (3 kHz to 30 kHz) communication systems are more suitable for wireless communication in underground or underwater environments due to greater skin depth. However, conventional very low frequency electric antennas face significant issues of large size and high power consumption to achieve sufficient radiation efficiency, which severely limits the miniaturization and portability of the antennas. Compared to conventional electric antennas, the recently emerging mechanical antennas can achieve low-frequency communication with a very small size. Currently, low-frequency mechanical antennas mainly include rotating permanent magnet antennas driven by external motors and magnetoelectric antennas with resonant piezoelectric layers. Magnetoelectric antennas primarily utilize electromechanical resonance to induce magnetic moment oscillation, allowing for a size reduction of five orders of magnitude compared to conventional electric antennas, while significantly reducing power consumption.

At present, there are very low frequency ME transceiver devices and magnetoelectric antennas with magnetostrictive layer/piezoelectric layer/magnetostrictive layer structures, but these antenna devices have the defect of weak emitted magnetic fields, which severely restricts the performance of low-frequency communication over long distances.

### SUMMARY

An objective of the present disclosure is to provide a low-frequency multiferroic mechanical antenna amplified with a multifunctional metamaterial beam, which can amplify an emitted magnetic field and enhance magnetic field emission efficiency.

To achieve the above objective, the present disclosure provides the following solutions.

The present disclosure provides a low-frequency multiferroic mechanical antenna amplified with a multifunctional metamaterial beam, including a magnetoelectric emission array, a composite beam, a metal spiral structure, a permanent magnet, and an energy harvesting circuit.

The magnetoelectric emission array includes a plurality of magnetoelectric emission units, where each magnetoelectric emission unit includes a strong-hysteresis piezomagnetic layer, a piezomagnetic film unit, and a piezoelectric layer arranged from top to bottom; the composite beam is set between the piezomagnetic film unit and the piezoelectric layer.

The composite beam includes a first elastic substrate, a flexible piezoelectric material polyvinylidene fluoride (PVDF) layer, and a second elastic substrate arranged from top to bottom; the first elastic substrate and the second elastic substrate each have a grid structure; one end of the composite beam is fixed to form a cantilever beam, and a width of the composite beam gradually decreases from the fixed end to a free end of the composite beam; the flexible piezoelectric material PVDF layer extends to form a rectangular PVDF surface electrode at the free end of the composite beam; the rectangular PVDF surface electrode is connected to the permanent magnet and the energy harvesting circuit.

The metal spiral structure is vertically arranged on an upper surface of the composite beam and includes a plurality of metal spiral units; each metal spiral unit is connected to a lumped capacitor and a negative resistance circuit; the lumped capacitor is connected in parallel with the negative resistance circuit; the rectangular PVDF surface electrode generates an alternating voltage when the composite beam vibrates, and supplies power to the negative resistance circuit through the energy harvesting circuit.

An input end of the piezoelectric layer is externally connected to an alternating voltage source; during an antenna transmission process, the piezoelectric layer generates alternating strain under the excitation of the alternating voltage, and transmits the alternating strain to the piezomagnetic film unit, causing magnetic moment oscillation; the composite beam converges the alternating strain generated by the magnetoelectric emission array, and regulates swing of the permanent magnet, modulating static magnetic energy of the permanent magnet into an alternating magnetic field.

Optionally, the piezomagnetic film unit extends out from edges of the strong-hysteresis piezomagnetic layer to form four trapezoidal structures, with narrow ends of the trapezoidal structures being close to the edges of the strong-hysteresis piezomagnetic layer.

Optionally, the grid structure of the first elastic substrate is arranged in a staggered grid pattern, and the metal spiral structure is fixedly connected to connecting beams between staggered parts of the grid structure of the first elastic substrate.

Optionally, the piezomagnetic film unit and the piezoelectric layer are connected to the composite beam in a bonded manner.

Optionally, the metal spiral structure is a square-shaped metal sheet.

Optionally, the first elastic substrate and the second elastic substrate each have a thickness ranging from 0.1 mm to 2 mm.

Optionally, the piezoelectric layer is made of a lead zirconate titanate (PZT) or lead magnesium niobate-lead titanate (PMN-PT) piezoelectric material.

Optionally, the strong-hysteresis piezomagnetic layer, the piezomagnetic film unit, and the piezoelectric layer each have a thickness ranging from 0.1 mm to 2 mm.

Optionally, the flexible piezoelectric material PVDF layer has a thickness ranging from 0.02 mm to 0.2 mm.

Optionally, the input end of the piezoelectric layer is externally connected to the alternating voltage source, and elastic standing waves generated by a piezoelectric layer array under the excitation of the alternating voltage source enhances a magnetic moment oscillation effect of the permanent magnet at the end of the beam through variable stiffness characteristics of the elastic substrate in the composite beam and strain convergence characteristics of a shuttle-shaped structure; vibration of the permanent magnet and a magnetostrictive effect of a piezomagnetic film together generate an emitted alternating magnetic field; the piezoelectric layer array is formed by all the piezoelectric layers.

According to specific examples provided in this application, this application discloses the following technical effects:

The present disclosure provides a low-frequency multiferroic mechanical antenna amplified with a multifunctional metamaterial beam, where the composite beam drives the swing of the permanent magnet at the free end under the excitation of the piezoelectric unit array, generating an alternating magnetic field; the equivalent inductance formed by the grid of the elastic substrate and the metal spiral structure, the distributed capacitance formed by the flexible piezoelectric material PVDF layer, and the lumped capacitance together form a low-frequency magnetic metamaterial, thereby amplifying evanescent waves by utilizing the negative permeability characteristics of the low-frequency magnetic metamaterial: at this time, the static magnetic energy controlling the magnetic moment oscillation of the magnetostrictive film can be enhanced through strong convergences of the magnetic field generated by adjacent magnetostrictive arrays, and the emitted magnetic field can be further amplified to improve emission efficiency without increasing the number of antennas and power consumption. The flexible piezoelectric material PVDF layer of the composite beam generates an alternating voltage under the action of alternating strain, which supplies power to the negative resistance circuit through the energy harvesting circuit, and the negative resistance circuit is connected in parallel with the low-frequency magnetic metamaterial to reduce the metamaterial resistance and improve the Q value, thereby further amplifying the emitted magnetic field.

### BRIEF DESCRIPTION OF THE DRAWINGS

To describe the technical solutions in the embodiments of the present disclosure or in the prior art more clearly, the following briefly describes the accompanying drawings required for the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a schematic structural diagram of a low-frequency multiferroic mechanical antenna amplified with a multifunctional metamaterial beam according to an embodiment of the present disclosure;

FIG. 2 is a schematic structural diagram of a magnetoelectric emission unit according to an embodiment of the present disclosure;

FIG. 3 is a schematic structural diagram of a composite beam according to an embodiment of the present disclosure;

FIG. 4 is a block diagram of an antenna transmission system according to an embodiment of the present disclosure.

### REFERENCE NUMERALS

1—strong-hysteresis piezomagnetic layer; 2—piezomagnetic film unit; 3—composite beam; 4—piezoelectric layer; 5—alternating voltage source; 6—permanent magnet; 7—metal spiral structure; 8—lumped capacitor; 9—negative resistance circuit; 10—energy harvesting circuit; 11—first elastic substrate; 12—flexible piezoelectric material PVDF layer; 13—second elastic substrate.

### DETAILED DESCRIPTION OF THE EMBODIMENTS

The technical solutions in the embodiments of the present disclosure are clearly and completely described below with reference to the drawings in the embodiments of the present disclosure. Apparently, the described embodiments are only some rather than all of the embodiments of the present disclosure. All other embodiments obtained by a person of ordinary skill in the art based on the embodiments of the present disclosure without creative efforts shall fall within the protection scope of the present disclosure.

Conventional magnetoelectric antennas still have the following problems: First, conventional magnetoelectric antennas typically require an external permanent magnet to provide an optimal bias magnetic field to achieve a strong radiated magnetic field at the transmission end and high sensitivity at the receiving end, which significantly increases the size and noise of the antenna. Besides, the magnetic field emission efficiency of current magnetoelectric antennas is still relatively low, which obviously limits the communication distance. Current conventional magnetoelectric antennas are mainly composed of magnetostrictive materials and piezoelectric layers, primarily achieving magnetic field emission and reception through the converse magnetoelectric effect at the transmission end and the magnetoelectric effect at the receiving end. However, there is a lack of corresponding array technology research, and there is a defect of weak emitted magnetic fields, which severely restricts the performance of low-frequency communication over long distances.

To make the above objectives, features, and advantages of the present disclosure more obvious and easy to understand, the present disclosure will be further described in detail with reference to the accompanying drawings and specific implementations.

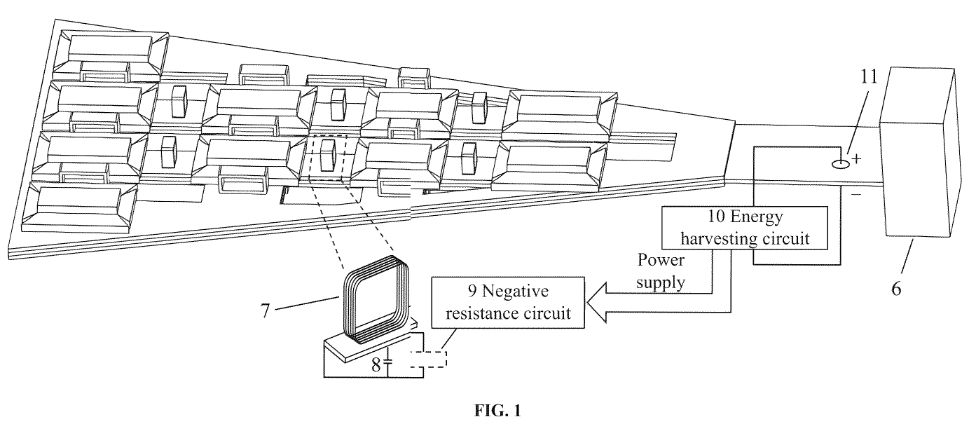

In an exemplary embodiment, as shown in FIG. 1, the present disclosure provides a low-frequency multiferroic mechanical antenna amplified with a multifunctional metamaterial beam, including a magnetoelectric emission array, a composite beam 3, a metal spiral structure 7, a permanent magnet 6, and an energy harvesting circuit 10.

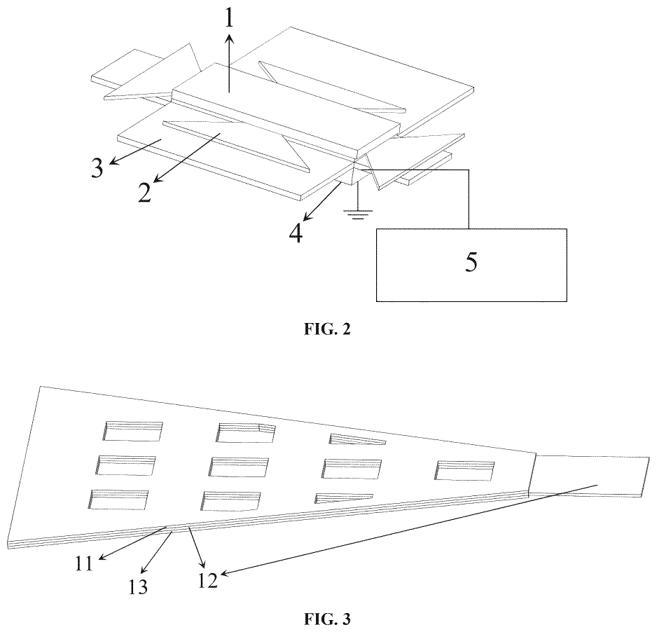

The magnetoelectric emission array includes a plurality of magnetoelectric emission units. As shown in FIG. 2, each magnetoelectric emission unit includes a strong-hysteresis piezomagnetic layer 1, a piezomagnetic film unit 2, and a piezoelectric layer 4 arranged from top to bottom. The piezomagnetic film unit 2 is a specially shaped piezomagnetic film with high magnetic permeability. The piezomagnetic film unit 2 extends out from edges of the strong-hysteresis piezomagnetic layer 1 to form four trapezoidal structures, with narrow ends of the trapezoidal structures being close to the edges of the strong-hysteresis piezomagnetic layer 1.

The piezoelectric layer 4 can be made of a piezoelectric material such as lead magnesium niobate-lead titanate (PMN-PT) or lead zirconate titanate (PZT). The strong-hysteresis piezomagnetic layer 1, the piezomagnetic film unit 2, and the piezoelectric layer 4 each have a thickness within a range of 0.1 mm to 2 mm. The magnetoelectric emission unit has a length within a range of 5 mm to 100 mm, and the spacing between magnetoelectric emission units is determined by a specified operating frequency, where center points of two adjacent magnetoelectric emission units are spaced apart by a distance ranging from 1 mm to 50 mm in a width direction and a distance ranging from 5 mm to 200 mm in a length direction.

The composite beam 3 is set between the piezomagnetic film unit 2 and the piezoelectric layer 4. As shown in FIG. 3, the composite beam 3 includes upper and lower layers made of metal material with the high elastic modulus and an intermediate layer made of flexible piezoelectric material (e.g., PVDF with the low elastic modulus), that is, the composite beam 3 includes a first elastic substrate 11, a flexible piezoelectric material PVDF layer 12, and a second elastic substrate 13 arranged from top to bottom, where the flexible piezoelectric material PVDF layer 12 have a thickness ranging from 0.02 mm to 0.2 mm, and the first elastic substrate 11 and the second elastic substrate 13 each have a thickness ranging from 0.1 mm to 2 mm.

The first elastic substrate 11 and the second elastic substrate 13 each have a grid structure. One end of the composite beam 3 is fixed to form a cantilever beam, and a beam width of the composite beam 3 gradually decreases from the fixed end to a free end of the composite beam 3, forming a shuttle-shaped structure. Therefore, the composite beam 3 is a grid-shaped shuttle cantilever beam with variable stiffness. The flexible piezoelectric material PVDF layer 12 extends to form a rectangular PVDF surface electrode at the free end of the composite beam 3 with the shuttle-shaped structure; the rectangular PVDF surface electrode is connected to the permanent magnet 6 and the energy harvesting circuit 10. The composite beam 3 utilizes the bending vibration amplification effect at the free end caused by the strain convergence effect and the variable stiffness effect of the shuttle-shaped structure, significantly improving the driving capability of the piezoelectric layer 4 on the permanent magnet 6 at the free end.

The present disclosure relates to very low frequency antennas for wireless communication in special environments such as underground or underwater, and in particular, to a high-emission-efficiency, low-frequency multiferroic mechanical antenna amplified with a multifunctional metamaterial beam. The low-frequency multiferroic mechanical antenna amplified with a multifunctional metamaterial beam provided by the present disclosure establishes an internal magnetic field between the strong-hysteresis piezomagnetic layer 1 and the piezomagnetic film unit 2, achieving optimal converse magnetoelectric performance of the magnetoelectric antenna in a zero-bias magnetic field. On one hand, the piezoelectric unit array under the excitation of the alternating voltage achieves strong coupling characteristics of the elastic field/magnetic field between array units through the elastic standing waves generated in the elastic substrate and the magnetic field convergence effect of the specially shaped high-magnetic-permeability film, enhancing the modulation of piezomagnetic film's magnetic moment oscillation, resulting in the nonlinearly enhanced emission field strength with the increased number of units, thereby overcoming the defects of low efficient modulation of magnetic moment in single magnetoelectric antenna with only elastic field, and significantly improving the magnetic field emission efficiency. On the other hand, the composite beam 3 generates bending vibrations under the alternating strain of the piezoelectric unit array, amplifying the swing amplitude of the permanent magnet 6 at the free end through the variable stiffness effect and the strain convergence effect of the shuttle-shaped structure, producing an alternating magnetic field.

In a specific example, the shape of the permanent magnet 6 can be a rectangular prism or other shapes with omnidirectional magnetic moments.

The piezomagnetic film unit 2 and the piezoelectric layer 4 are connected to the composite beam 3 in a bonded manner. Specifically, the strong-hysteresis piezomagnetic layer 1, the piezomagnetic film unit 2, and the piezoelectric layer 4 are bonded at staggered parts, and the metal spiral structure 7 is fixed to connecting beams between the staggered parts, with the axis of the metal spiral structure 7 parallel to the direction of the connecting beam.

The grid-shaped first elastic substrate 11 and second elastic substrate 13 are arranged in a staggered grid pattern; the metal spiral structure 7 is fixedly connected to the connecting beams between staggered parts of the grid structure of the first elastic substrate 11. Furthermore, the metal spiral structure 7 is vertically arranged at the upper surface of the composite beam 3, that is, vertically arranged at the first elastic substrate 11, and includes a plurality of metal spiral units. In addition to the distributed capacitance formed by the flexible piezoelectric material PVDF layer 12 of the composite beam 3, an additional lumped capacitor 8 is connected in series to adjust the resonant frequency of the low-frequency magnetic metamaterial. Each metal spiral unit is connected to a lumped capacitor 8 and a negative resistance circuit 9, with the lumped capacitor 8 and the negative resistance circuit 9 connected in parallel; the rectangular PVDF surface electrode generates an alternating voltage when the composite beam vibrates, which supplies power to the negative resistance circuit 9 through the energy harvesting circuit 10. The metal spiral structure 7 is a square-shaped metal sheet. The metal spiral structure 7, the first elastic substrate 11, and the second elastic substrate 13 are made of the same material, which can be metal material with the high elastic modulus and high electrical conductivity. The metal spiral structure 7 has a side length ranging from 5 mm to 50 mm and a width ranging from 1 mm to 100 mm.

An input end of the piezoelectric layer 4 is externally connected to an alternating voltage source 5; during an antenna transmission process, the piezoelectric layer 4 generates alternating strain under the excitation of alternating voltage, and transmits the alternating strain to the piezomagnetic film unit 2, causing magnetic moment oscillation; the composite beam 3 converges the alternating strain generated by the magnetoelectric emission array, and regulates the swing of permanent magnet 6, modulating static magnetic energy of the permanent magnet 6 into an alternating magnetic field. The voltage amplitude of alternating voltage source 5 does not exceed 200V.

The alternating voltage source 5 excites the piezoelectric layer array (the piezoelectric layer array consists of all piezoelectric layers 4) to generate elastic standing waves, which enhance the magnetic moment oscillation effect of the permanent magnet 6 at the end of the beam through the variable stiffness characteristics of the elastic substrate in the composite beam 3 and the strain convergence characteristics of the shuttle-shaped structure. The vibration of the permanent magnet 6 and the magnetostrictive effect of the piezomagnetic film together generate the emitted alternating magnetic field.

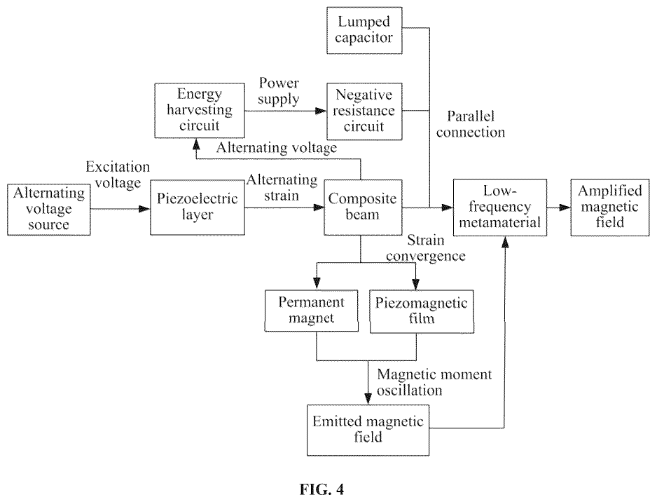

As shown in FIG. 4, during the transmission process of antenna, the alternating voltage source 5 first generates an alternating voltage to excite the array of piezoelectric layers 4. The array of piezoelectric layers 4 produces alternating strain. The alternating strain generated by the array of piezoelectric layers 4 arranged at specific intervals at the lower surface of the composite beam 3 is superimposed and converged through the composite beam 3, driving the magnetic moment resonance of the piezomagnetic film units 2 at the corresponding upper surface. The bias magnetic field of each piezomagnetic film unit 2 is provided by the non-volatile static magnetic energy of the strong-hysteresis piezomagnetic layer 1, and there are strong magnetic field coupling effects between multiple piezomagnetic film units 2. More importantly, to further enhance the strong magnetic field coupling effect between the magnetoelectric units and the total emitted magnetic field, this embodiment utilizes the grid-shaped shuttle beam 3 with variable stiffness to converge the alternating strain generated by the magnetoelectric emission antenna array and regulate the swing of the permanent magnet 6 at the free end of the cantilever beam, thereby modulating the static magnetic energy of the permanent magnet 6 into an alternating magnetic field.

The low-frequency multiferroic mechanical antenna amplified with a multifunctional metamaterial beam provided by the present disclosure consists of an array formed by multiple units each consisting of a strong-hysteresis piezomagnetic layer 1, a high-magnetic-permeability piezomagnetic film unit 2, and a piezoelectric layer 4, a grid-shaped shuttle composite beam 3 with variable stiffness that is composed of a first elastic substrate 11, a flexible piezoelectric material PVDF layer 12, and a second elastic substrate 13, a permanent magnet 6, an energy harvesting circuit 10, and a negative resistance circuit 9. The composite beam 3 is fixed at the wider end, and the narrower end extends to form a rectangular PVDF surface electrode for connection to the permanent magnet 6. The composite beam 3 generates bending vibrations (the elastic substrate generates bending vibration modes) under the action of the alternating strain of the piezoelectric layer 4, amplifying the amplitude of the permanent magnet 6 at the free end through the variable stiffness effect of the cross-section and the strain convergence effect of the horizontal shuttle-shaped structure, thereby enhancing the magnetic moment oscillation of the permanent magnet 6. The permanent magnet 6 and the piezomagnetic film unit 2 work together to generate an alternating magnetic field.

Meanwhile, the flexible piezoelectric material PVDF layer 12 in the composite beam 3 acts as a dielectric material to form distributed capacitance. The planar grid structure of the elastic substrate and the vertical metal spiral structure, along with their own distributed capacitance and the series lumped capacitor 8, together form a low-frequency magnetic metamaterial (i.e., the planar grid structure of the elastic substrate and the vertical metal spiral structure 7, by cascading with an external lumped capacitor 8, form a low-frequency magnetic metamaterial with their own distributed capacitance). The evanescent waves are amplified by using the negative permeability characteristics of the low-frequency magnetic metamaterial, thereby amplifying the emitted magnetic field.

At this time, the magnetic field generated by the permanent magnet 6 and the piezomagnetic film is amplified through the metamaterial beam, which can converge the magnetic field generated by adjacent magnetostrictive arrays, enhancing the static magnetic energy that controls the magnetic moment oscillation of the piezomagnetic film unit 2, while further amplifying the emitted magnetic field without increasing the number of antennas and power consumption, thus improving magnetic field emission efficiency. On the other hand, PVDF acts as a piezoelectric material, that is, the flexible piezoelectric material PVDF layer 12 generates an alternating voltage under the action of alternating strain when the composite beam 3 vibrates, which supplies power to the negative resistance circuit 9 after passing through the energy harvesting circuit 10. The negative resistance circuit 9, when connected in parallel with the low-frequency magnetic metamaterial, reduces the resistance of the metamaterial and increases the corresponding Q value, thereby further amplifying the emitted magnetic field without consuming additional energies.

The technical characteristics of above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

Several examples are used herein for illustration of the principles and implementations of this application. The description of the foregoing examples is used to help illustrate the method of this application and the core principles thereof. In addition, those of ordinary skill in the art can make various modifications in terms of specific implementations and scope of application in accordance with the teachings of this application. In conclusion, the content of the present specification shall not be construed as a limitation to the present disclosure.

What is claimed is:

1. A low-frequency multiferroic mechanical antenna amplified with a multifunctional metamaterial beam, comprising a magnetoelectric emission array, a composite beam, a metal spiral structure, a permanent magnet, and an energy harvesting circuit;
wherein the magnetoelectric emission array comprises a plurality of magnetoelectric emission units, and each magnetoelectric emission unit comprises a strong-hysteresis piezomagnetic layer, a piezomagnetic film unit, and a piezoelectric layer arranged from top to bottom; the composite beam is set between the piezomagnetic film unit and the piezoelectric layer;
the composite beam comprises a first elastic substrate, a flexible piezoelectric material polyvinylidene fluoride (PVDF) layer, and a second elastic substrate arranged from top to bottom; the first elastic substrate and the second elastic substrate each have a grid structure; one end of the composite beam is fixed to form a cantilever beam, and a width of the composite beam gradually decreases from the fixed end to a free end of the composite beam; the flexible piezoelectric material PVDF layer extends to form a rectangular PVDF surface electrode at the free end of the composite beam; the rectangular PVDF surface electrode is connected to the permanent magnet and the energy harvesting circuit;
the metal spiral structure is vertically arranged at an upper surface of the composite beam and comprises a plurality of metal spiral units; each metal spiral unit is connected to a lumped capacitor and a negative resistance circuit; the lumped capacitor is connected in parallel with the negative resistance circuit; the rectangular PVDF surface electrode generates an alternating voltage when the composite beam vibrates, and supplies power to the negative resistance circuit through the energy harvesting circuit; and
an input end of the piezoelectric layer is externally connected to an alternating voltage source; during a transmission process of an antenna, the piezoelectric layer generates alternating strain under the excitation of the alternating voltage, and transmits the alternating strain to the piezomagnetic film unit, causing magnetic moment oscillations; the composite beam converges the alternating strain generated by the magnetoelectric emission array, and regulates swing of the permanent magnet, modulating static magnetic energy of the permanent magnet into an alternating magnetic field.

2. The low-frequency multiferroic mechanical antenna amplified with a multifunctional metamaterial beam according to claim 1, wherein the piezomagnetic film unit extends out from edges of the strong-hysteresis piezomagnetic layer to form four trapezoidal structures, with narrow ends of the trapezoidal structures being close to the edges of the strong-hysteresis piezomagnetic layer.

3. The low-frequency multiferroic mechanical antenna amplified with a multifunctional metamaterial beam according to claim 1, wherein the grid structure of the first elastic substrate is arranged in a staggered grid pattern, and the metal spiral structure is fixedly connected to connecting beams between staggered parts of the grid structure of the first elastic substrate.

4. The low-frequency multiferroic mechanical antenna amplified with a multifunctional metamaterial beam according to claim 1, wherein the piezomagnetic film unit and the piezoelectric layer are connected to the composite beam in a bonded manner.

5. The low-frequency multiferroic mechanical antenna amplified with a multifunctional metamaterial beam according to claim 1, wherein the metal spiral structure is a square-shaped metal sheet.

6. The low-frequency multiferroic mechanical antenna amplified with a multifunctional metamaterial beam according to claim 1, wherein the first elastic substrate and the second elastic substrate each have a thickness ranging from 0.1 mm to 2 mm.

7. The low-frequency multiferroic mechanical antenna amplified with a multifunctional metamaterial beam according to claim 1, wherein the piezoelectric layer is made of a lead zirconate titanate (PZT) or lead magnesium niobate-lead titanate (PMN-PT) piezoelectric material.

8. The low-frequency multiferroic mechanical antenna amplified with a multifunctional metamaterial beam according to claim 1, wherein the strong-hysteresis piezomagnetic layer, the piezomagnetic film unit, and the piezoelectric layer each have a thickness ranging from 0.1 mm to 2 mm.

9. The low-frequency multiferroic mechanical antenna amplified with a multifunctional metamaterial beam according to claim 1, wherein the flexible piezoelectric material PVDF layer has a thickness ranging from 0.02 mm to 0.2 mm.

10. The low-frequency multiferroic mechanical antenna amplified with a multifunctional metamaterial beam according to claim 1, wherein the input end of the piezoelectric layer is externally connected to the alternating voltage source, and elastic standing waves generated by a piezoelectric layer array under the excitation of the alternating voltage source enhances a magnetic moment oscillation effect of the permanent magnet at the end of the beam through variable stiffness characteristics of the elastic substrate in the composite beam and strain convergence characteristics of a shuttle-shaped structure; vibration of the permanent magnet and a magnetostrictive effect of a piezomagnetic film together generate an emitted alternating magnetic field; the piezoelectric layer array is formed by all the piezoelectric layers.
